(19) United States
(12) Patent Application Publication
(10) Pub. No.: US 2024/0178287 A1
(43) Pub. Date: May 30, 2024

(54) SEMICONDUCTOR DEVICE WITH ENERGY-REMOVABLE LAYER AND METHOD FOR FABRICATING THE SAME

(71) Applicant: NANYA TECHNOLOGY CORPORATION, New taipei City (TW)

(72) Inventor: TSE-YAO HUANG, TAIPEI CITY (TW)

(21) Appl. No.: 17/994,106

(22) Filed: Nov. 25, 2022

(51) Int. Cl. H01L 29/417; H01L 29/40; H01L 29/45; H01L 29/49

(52) U.S. Cl. CPC H01L 29/41775; H01L 29/401; H01L 29/45; H01L 29/4983

(57) ABSTRACT

The present application discloses a semiconductor device and a method for fabricating the semiconductor device. The semiconductor device includes a substrate; a first gate structure positioned on the substrate; a second gate structure positioned on the substrate and next to the first gate structure; a layer of energy-removable material positioned on the substrate and between the first gate structure and the second gate structure; a dielectric layer positioned on the substrate and covering the first gate structure and the second gate structure; and a first opening positioned along the dielectric layer to expose the layer of energy-removable material.

### TECHNICAL FIELD

The present disclosure relates to a semiconductor device and a method for fabricating the semiconductor device, and more particularly, to a semiconductor device with an energy-removable layer and a method for fabricating the semiconductor device with the energy-removable layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a first gate structure positioned on the substrate; a second gate structure positioned on the substrate and next to the first gate structure; a layer of energy-removable material positioned on the substrate and between the first gate structure and the second gate structure; a dielectric layer positioned on the substrate and covering the first gate structure and the second gate structure; and a first opening positioned along the dielectric layer to expose the layer of energy-removable material.

Another aspect of the present disclosure provides a semiconductor device including a substrate; a first gate structure positioned on the substrate; a second gate structure positioned on the substrate and next to the first gate structure; a lower portion positioned between the first gate structure and the second gate structure; an upper portion positioned on the lower portion; and a plurality of first spacers positioned between lower portion and the first gate structure and between the lower portion and the second gate structure. The lower portion and the upper portion configure a contact structure. A width of the upper portion is greater than a width of the lower portion.

Another aspect of the present disclosure provides a method for fabricating a semiconductor device including providing a substrate; forming a first gate structure and a second gate structure on the substrate; forming a plurality of first spacers on sidewalls of the first gate structure and the second gate structure; forming a layer of energy-removable material between the first gate structure and the second gate structure; forming a dielectric layer covering the first gate structure, the second gate structure, and the layer of energy-removable material; forming a first opening along the dielectric layer to expose the layer of energy-removable material; removing the layer of energy-removable material to form a contact opening communicated with the first opening; and forming a contact structure in the contact opening and the first opening.

Due to the design of the semiconductor device of the present disclosure, the layer of energy-removable material may be selectively removed. Therefore, no additional etching stop layer is needed for forming the contact structure. That is, the short issue originating from an etching stop layer and the contact structure may be avoided. As a result, the yield of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 15 illustrate, in schematic cross-sectional view diagrams, a flow for fabricating the semiconductor device in accordance with one embodiment of the present disclosure;

FIGS. 16 and 17 illustrate, in schematic cross-sectional view diagrams, a flow for fabricating a semiconductor device in accordance with another embodiment of the present disclosure;

FIGS. 18 to 23 illustrate, in schematic cross-sectional view diagrams, a flow for fabricating a semiconductor device in accordance with another embodiment of the present disclosure; and

FIGS. 24 to 26 illustrate, in schematic cross-sectional view diagrams, a flow for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

It should be noted that the terms “forming,” “formed” and “form” may mean and include any method of creating, building, patterning, implanting, or depositing an element, a dopant, or a material. Examples of forming methods may include, but are not limited to, atomic layer deposition, chemical vapor deposition, physical vapor deposition, sputtering, co-sputtering, spin coating, diffusing, depositing, growing, implantation, photolithography, dry etching, and wet etching.

It should be noted that, in the description of the present disclosure, the functions or steps noted herein may occur in an order different from the order noted in the figures. For example, two figures shown in succession may in fact be executed substantially concurrently or may sometimes be executed in a reversed order, depending upon the functionalities or steps involved.

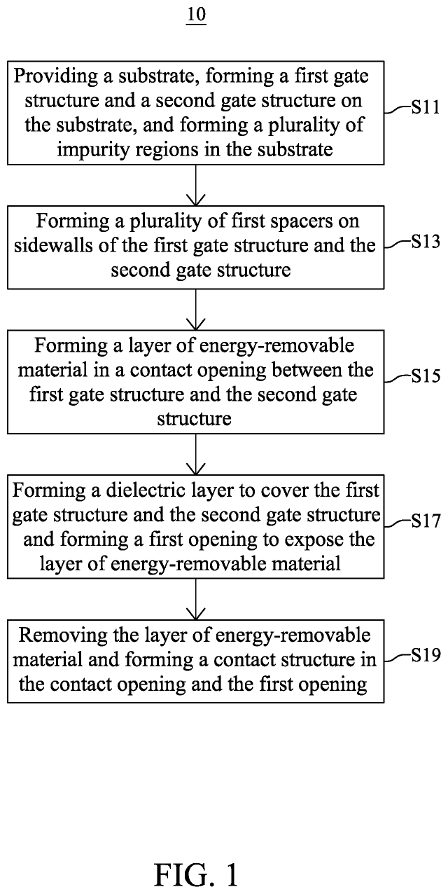

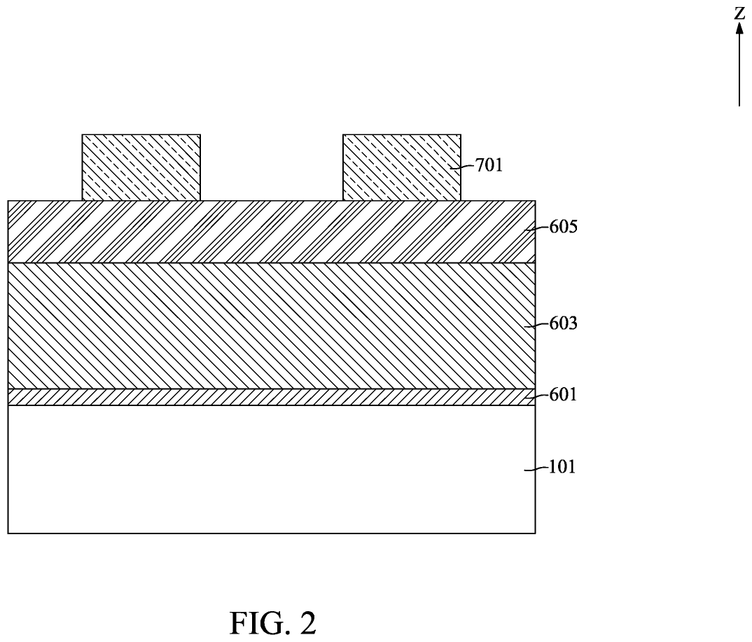

FIG. 1 illustrates, in a flowchart diagram form, a method 10 for fabricating a semiconductor device 1A in accordance with one embodiment of the present disclosure. FIGS. 2 to 15 illustrate, in schematic cross-sectional view diagrams, a flow for fabricating the semiconductor device 1A in accordance with one embodiment of the present disclosure.

With reference to FIGS. 1 to 5, at step S11, a substrate 101 may be provided, a first gate structure 310 and a second gate structure 320 may be formed on the substrate 101, and a plurality of impurity regions 103 may be formed in the substrate 101.

With reference to FIG. 2, the substrate 101 may include a bulk semiconductor substrate that is composed of at least one semiconductor material. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or 1I-VI compound semiconductor; or combinations thereof.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm. The insulator layer may eliminate leakage current between adjacent elements in the substrate 101 and reduce parasitic capacitance associated with source/drains.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIG. 2, a layer of first insulating material 601 may be formed on the substrate 101. In some embodiments, the first insulating material 601 may be, for example, a high-k material, an oxide, a nitride, an oxynitride or combinations thereof. In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof. In some embodiments, the layer of first insulating material 601 may be formed by, for example, chemical vapor deposition, atomic layer deposition, or other applicable deposition process.

With reference to FIG. 2, a layer of first conductive material 603 may be formed on the layer of first insulating material 601. In some embodiments, the first conductive material 603 may be, for example, a metal, a metal nitride, or a combination thereof. In some embodiments, the metal may be tungsten, aluminum, titanium, copper, or the like. For example, the layer of first conductive material 603 may be formed of titanium nitride, tungsten, or a titanium nitride/tungsten stacked structure. In some embodiments, the first conductive material 603 may be, for example, polycrystalline silicon, polycrystalline silicon germanium, or a combination thereof. In some embodiments, the layer of first conductive material 603 may be doped with a dopant such as phosphorus, arsenic, antimony, or boron.

With reference to FIG. 2, a layer of second insulating material 605 may be formed on the layer of first conductive material 603. In some embodiments, the second insulating material 605 may be, for example, silicon oxide, silicon nitride, silicon oxynitride, silicon nitride oxide, or other applicable dielectric materials. In some embodiments, the layer of second insulating material 605 may be formed by, for example, chemical vapor deposition, plasma-enhanced chemical vapor deposition, or other applicable deposition processes.

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIG. 2, a first mask layer 701 may be formed on the layer of second insulating material 605. The first mask layer 701 may include the pattern of the first gate structure 310 and the second gate structure 320. In some embodiments, the first mask layer 701 may be a photoresist layer.

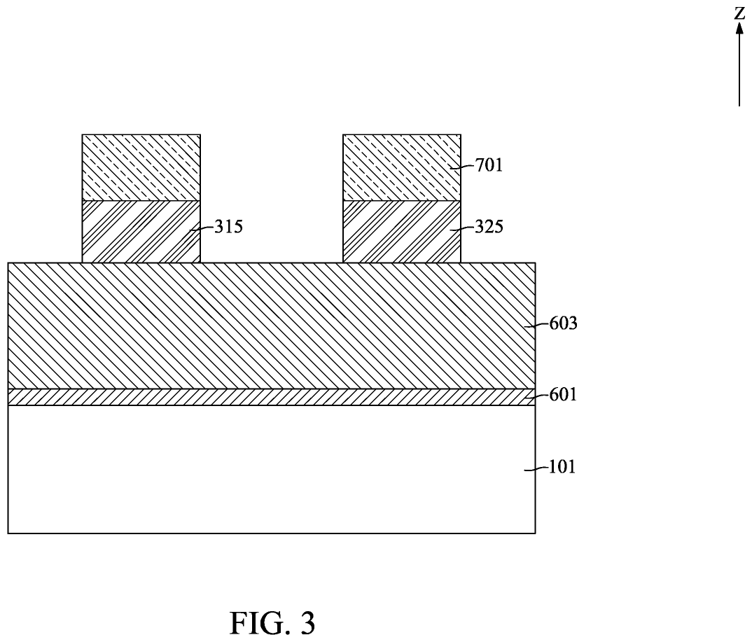

With reference to FIG. 3, a first etching process may be performed to remove a portion of the layer of second insulating material 605 to transfer the pattern of the first mask layer 701 to the layer of second insulating material 605. After the first etching process, the remaining second insulating material 605 may be turned into a first gate capping layer 315 and a second gate capping layer 325 formed on the layer of first conductive material 603 and separated from each other. In some embodiments, the etch rate ratio of the second insulating material 605 to the first mask layer 701 may be between about 100:1 and about 1.05:1, between about 15:1 and about 2:1, or between about 10:1 and about 2:1 during the first etching process. In some embodiments, the etch rate ratio of the second insulating material 605 to the first conductive material 603 may be between about 100:1 and about 1.05:1, between about 15:1 and about 2:1, or between about 10:1 and about 2:1 during the first etching process. After the formation of the first gate capping layer 315 and the second gate capping layer 325, the first mask layer 701 may be removed.

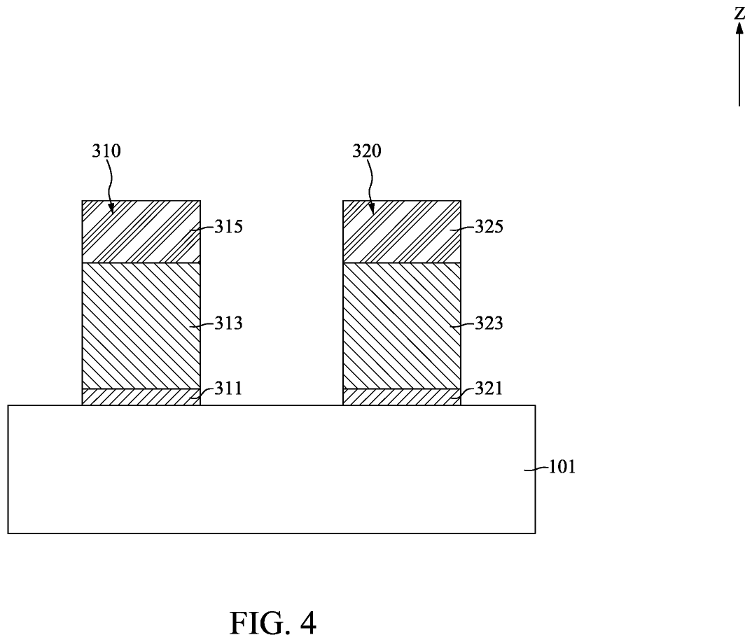

With reference to FIG. 4, a second etching process may be performed using the first gate capping layer 315 and the second gate capping layer 325 as masks to remove a portion of the layer of first conductive material 603 and a portion of the layer of first insulating material 601 to transfer the pattern of the first gate structure 310 and the second gate structure 320 to the layer of first conductive material 603 and the layer of first insulating material 601. After the second etching process, the remaining first conductive material 603 may be turned into a first gate conductive layer 313 and a second gate conductive layer 323 below the first gate capping layer 315 and the second gate capping layer 325, respectively and correspondingly. The remaining first insulating material 601 may be turned into a first gate insulating layer 311 and a second gate insulating layer 321 below the first gate conductive layer 313 and the second gate conductive layer 323, respectively and correspondingly.

In some embodiments, the second etching process may be a multi-stage etching process. For example, the second etching process is a two-stage dry etching process. The etching selectivity may be different for different stages. In some embodiments, the etch rate ratio of the first conductive material 603 to the first gate capping layer 315 (or the second gate capping layer 325) may be between about 100:1 and about 1.05:1, between about 15:1 and about 2:1, or between about 10:1 and about 2:1 during the second etching process. In some embodiments, the etch rate ratio of the first conductive material 603 to the substrate 101 may be between about 100:1 and about 1.05:1, between about 15:1 and about 2:1, or between about 10:1 and about 2:1 during the second etching process.

In some embodiments, the etch rate ratio of the first insulating material 601 to the first gate capping layer 315 (or the second gate capping layer 325) may be between about 100:1 and about 1.05:1, between about 15:1 and about 2:1, or between about 10:1 and about 2:1 during the second etching process. In some embodiments, the etch rate ratio of the first insulating material 601 to the substrate 101 may be between about 100:1 and about 1.05:1, between about 15:1 and about 2:1, or between about 10:1 and about 2:1 during the second etching process.

With reference to FIG. 4, the first gate insulating layer 311, the first gate conductive layer 313, and the first gate capping layer 315 configure the first gate structure 310. The second gate insulating layer 321, the second gate conductive layer 323, and the second gate capping layer 325 configure the second gate structure 320. The first gate structure 310 and the second gate structure 320 are disposed on the substrate 101 and separated from each other.

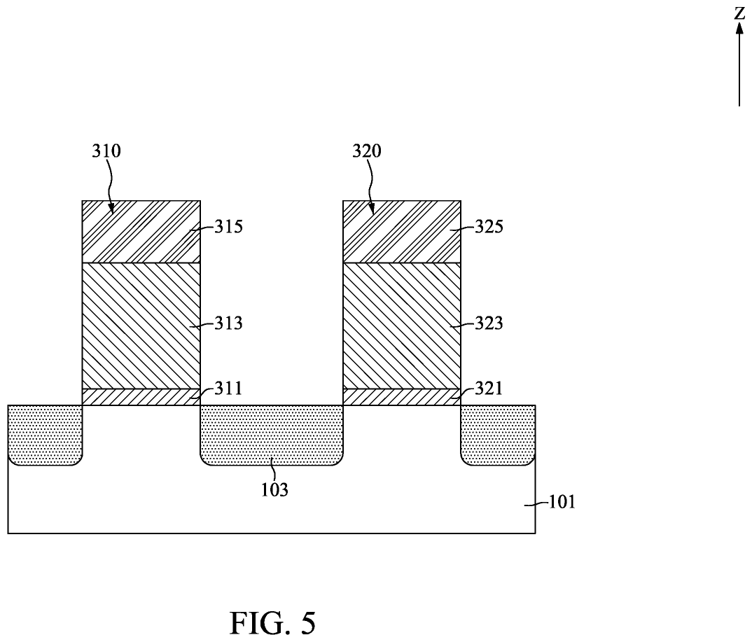

With reference to FIG. 5, the plurality of impurity regions 103 may be formed in the substrate 101. The plurality of impurity regions 103 may be formed between the first gate structure 310 and the second gate structure 320 and adjacent to the first gate structure 310 and the second gate structure 320, respectively and correspondingly. The plurality of impurity regions 103 may be formed by an implantation process. The implantation process may employ, for example, n-type dopants. The n-type dopants may be added to an intrinsic semiconductor to contribute free electrons to the intrinsic semiconductor. In a silicon-containing substrate, examples of n-type dopants, i.e., impurities, include but are not limited to antimony, arsenic, and phosphorus. In some embodiments, the dopant concentration of the plurality of impurity regions 103 may be between about 1E19 atoms/cm\hat{ }3 and about 1E21 atoms/cm\hat{ }3; although other dopant concentrations that are lesser than, or greater than, the aforementioned range may also be employed in the present application.

In some embodiments, an annealing process may be performed to activate the plurality of impurity regions 103. The annealing process may have a process temperature between about 800° C. and about 1250° C. The annealing process may have a process duration between about 1 millisecond and about 500 milliseconds. The annealing process may be, for example, a rapid thermal anneal, a laser spike anneal, or a flash lamp anneal.

With reference to FIGS. 1, 6 and 7, at step S13, a plurality of first spacers 401 may be formed on sidewalls 310S, 320S of the first gate structure 310 and the second gate structure 320.

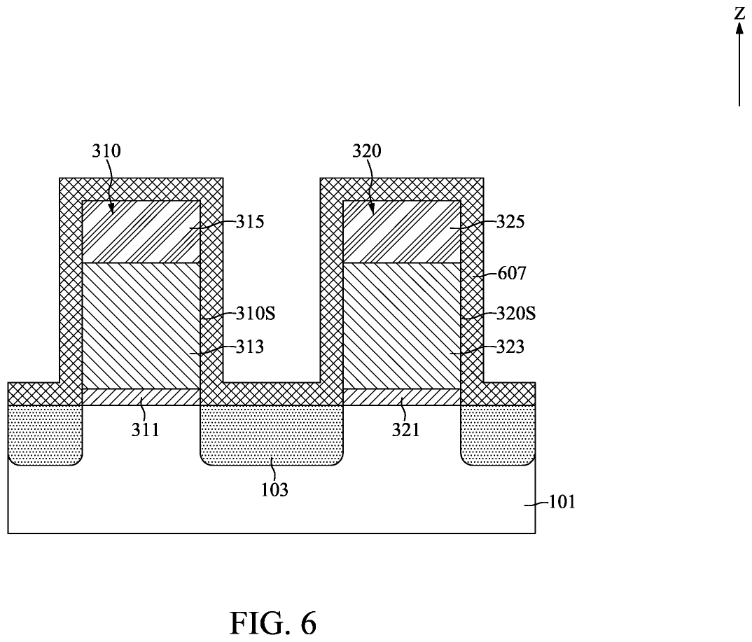

With reference to FIG. 6, a layer of first spacer material 607 may be conformally formed to cover the substrate 101, the first gate structure 310, and the second gate structure 320. In some embodiments, the first spacer material 607 may be, for example, silicon oxide, silicon nitride, silicon nitride oxide, silicon oxynitride, or a combination thereof. In some embodiments, the layer of first spacer material 607 may be formed by, for example, atomic layer deposition, chemical vapor deposition, or other applicable deposition processes.

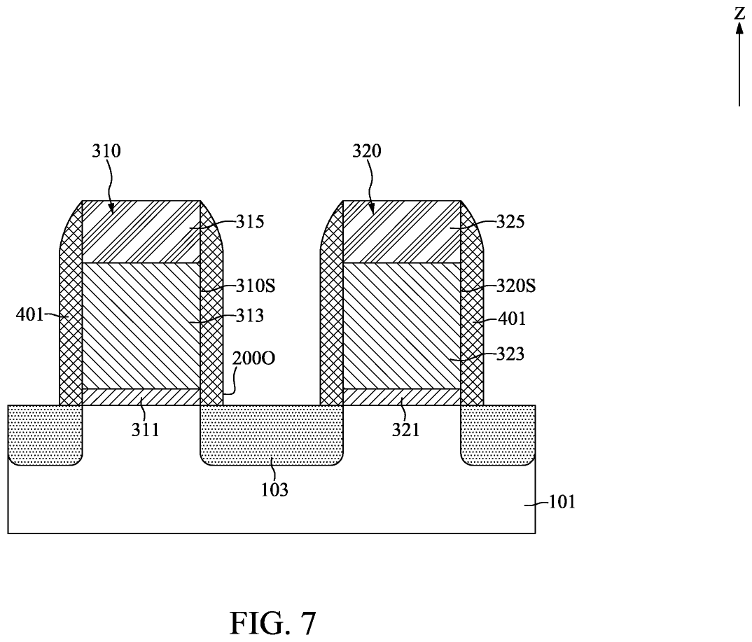

With reference to FIG. 7, a first spacer etching process may be performed to remove a portion of the layer of first spacer material 607. In some embodiments, the first spacer etching process may be an anisotropic etching process such as an anisotropic dry etching process. In some embodiments, the etch rate ratio of the first spacer material 607 to the plurality of impurity regions 103 may be between about 100:1 and about 1.05:1, between about 15:1 and about 2:1, or between about 10:1 and about 2:1 during the first spacer etching process.

With reference to FIG. 1 and FIGS. 8 to 10, at step S15, a layer of energy-removable material 609 may be formed in a contact opening 2000 between the first gate structure 310 and the second gate structure 320.

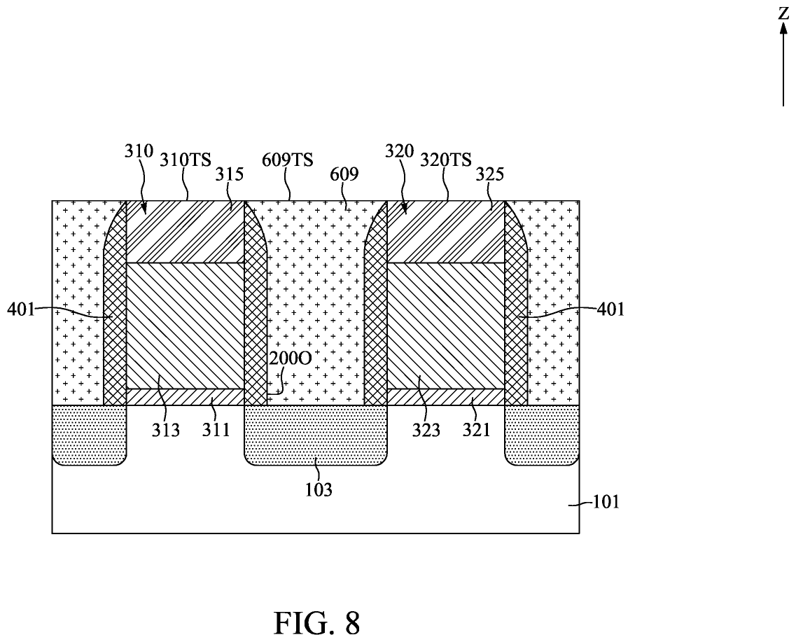

With reference to FIG. 8, the layer of energy-removable material 609 may be formed to cover the first gate structure 310 and the second gate structure 320. A planarization process, such as chemical mechanical polishing, may be performed until the top surface of the first gate capping layer 315 (or the second gate capping layer 325) is exposed to remove excess material and provide a substantially flat surface for subsequent processing steps. That is, the top surface 310TS (i.e., the top surface of the first gate capping layer 315) of the first gate structure 310, the top surface 320TS (i.e., the top surface of the second gate capping layer 325) of the second gate structure 320, and the top surface 609TS of the layer of energy-removable material 609 are substantially coplanar.

It should be noted that, in the description of the present disclosure, a surface of an element (or a feature) located at the highest vertical level along the dimension Z is referred to as a top surface of the element (or the feature). A surface of an element (or a feature) located at the lowest vertical level along the dimension Z is referred to as a bottom surface of the element (or the feature).

In some embodiments, the energy-removable material 609 may be, for example, a thermal decomposable material, a photonic decomposable material, an e-beam decomposable material, or a combination thereof. In some embodiments, the layer of energy-removable material 609 include a base material and a decomposable porogen material that is sacrificially removed upon being exposed to an energy source. The base material may include a methylsilsesquioxane based material. The decomposable porogen material may include a porogen organic compound that provides porosity to the base material of the energy-removable material.

In some embodiments, the energy-removable material 609 may include a relatively high concentration of the decomposable porogen material and a relatively low concentration of the base material but is not limited thereto. For example, the energy-removable material 609 may include about 75% or greater of the decomposable porogen material, and about 25% or less of the base material. In another example, the energy-removable material 609 may include about 95% or greater of the decomposable porogen material, and about 5% or less of the base material. In another example, the energy-removable material 609 may include about 100% of the decomposable porogen material, and no base material is used.

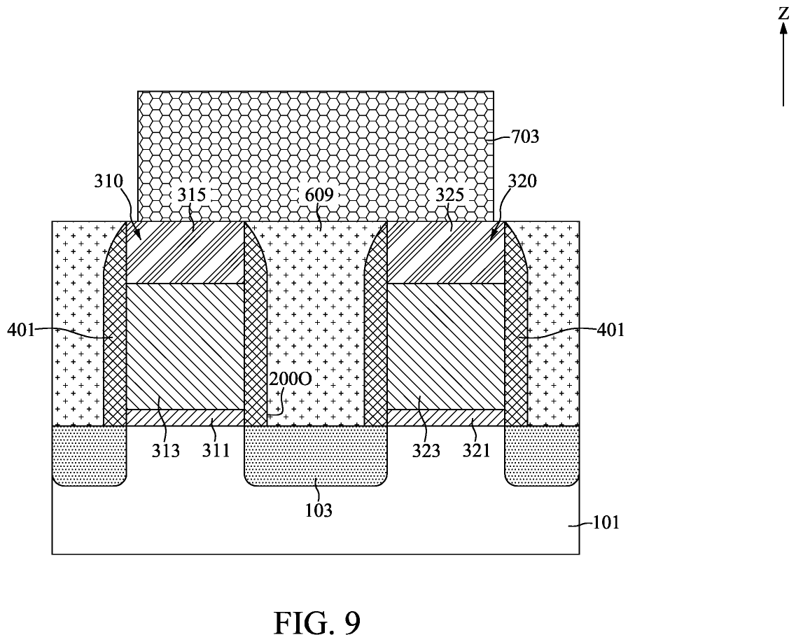

With reference to FIG. 9, a second mask layer 703 may be formed on the first gate structure 310 and the second gate structure 320 and cover a portion of the layer of energy-removable material 609. The space between the first gate structure 310 and the second gate structure 320 may be referred to as the contact opening 2000. The second mask layer 703 may cover the layer of energy-removable material 609 formed in the contact opening 2000.

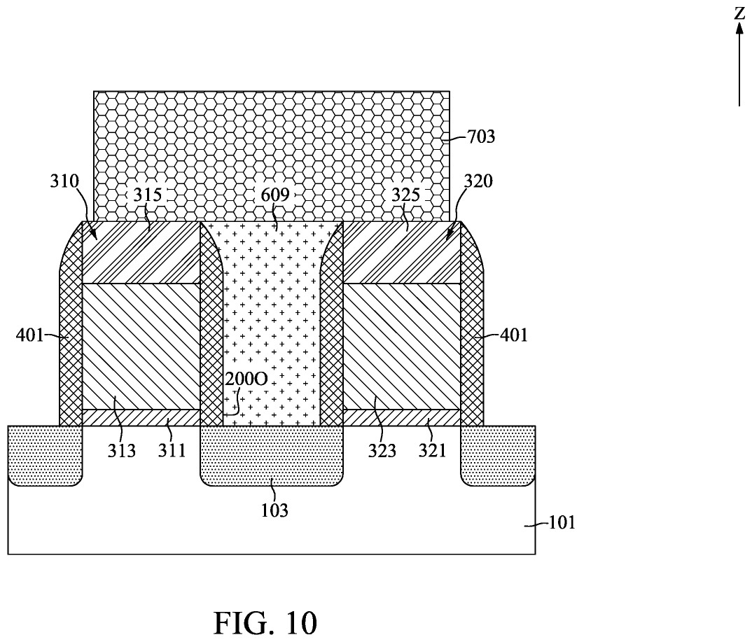

With reference to FIG. 10, a first removal process may be performed to remove the layer of energy-removable material 609 not covered by the second mask layer 703. In some embodiments, the first removal process may be an etching process such as a wet etching process. In some embodiments, the first removal process may be an energy treatment using an energy source. The energy source may include heat, light, or a combination thereof. When heat is used as the energy source, a temperature of the energy treatment may be between about 800° C. and about 900° C. When light is used as the energy source, an ultraviolet light may be applied. The second mask layer 703 may be removed after the first removal process.

In some embodiments, the removal rate ratio of the energy-removable material 609 to the impurity regions 103 may be between about 100:1 and about 1.05:1, between about 15:1 and about 2:1, or between about 10:1 and about 2:1 during the first removal process. In some embodiments, the removal rate ratio of the energy-removable material 609 to the first spacers 401 may be between about 100:1 and about 1.05:1, between about 15:1 and about 2:1, or between about 10:1 and about 2:1 during the first removal process. In some embodiments, the removal rate ratio of the energy-removable material 609 to the second mask layer 703 may be between about 100:1 and about 1.05:1, between about 15:1 and about 2:1, or between about 10:1 and about 2:1 during the first removal process.

With reference to FIG. 1 and FIGS. 11 to 13, at step S17, a dielectric layer 105 may be formed to cover the first gate structure 310 and the second gate structure 320 and a first opening 1050 may be formed to expose the layer of energy-removable material 609.

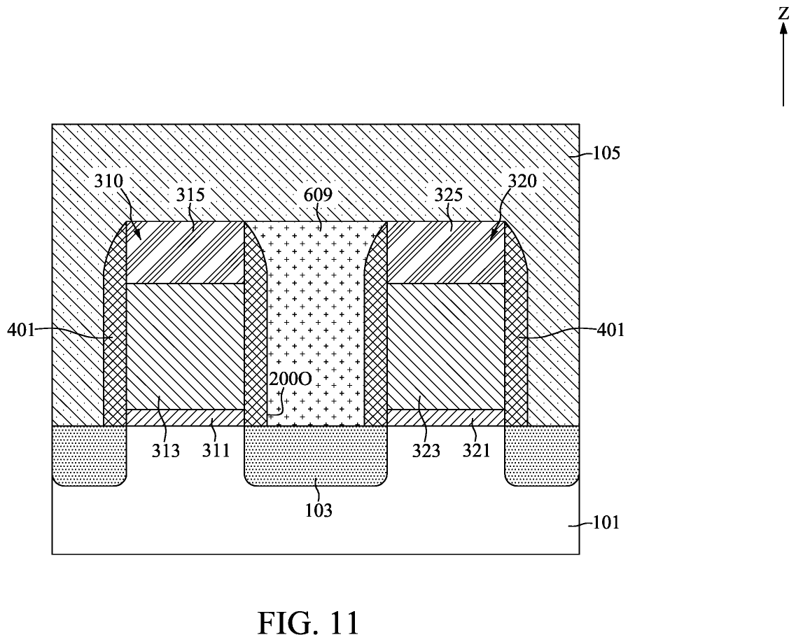

With reference to FIG. 11, in some embodiments, the dielectric layer 105 may be formed to cover the first gate structure 310, the second gate structure 320, and the layer of energy-removable material 609 in the contact opening 2000. A planarization process, such as chemical mechanical polishing, may be performed to remove excess material and provide a substantially flat surface for subsequent processing steps. The dielectric layer 105 may include, for example, silicon oxide, undoped silicate glass, fluorosilicate glass, borophosphosilicate glass, a spin-on low-k dielectric layer, a chemical vapor deposition low-k dielectric layer, or a combination thereof. In some embodiments, the dielectric layer 105 may include a self-planarizing material such as a spin-on glass or a spin-on low-k dielectric material such as SiLK™. In some embodiments, the dielectric layer 105 may be formed by a deposition process including, for example, chemical vapor deposition, plasma enhanced chemical vapor deposition, evaporation, or spin-on coating.

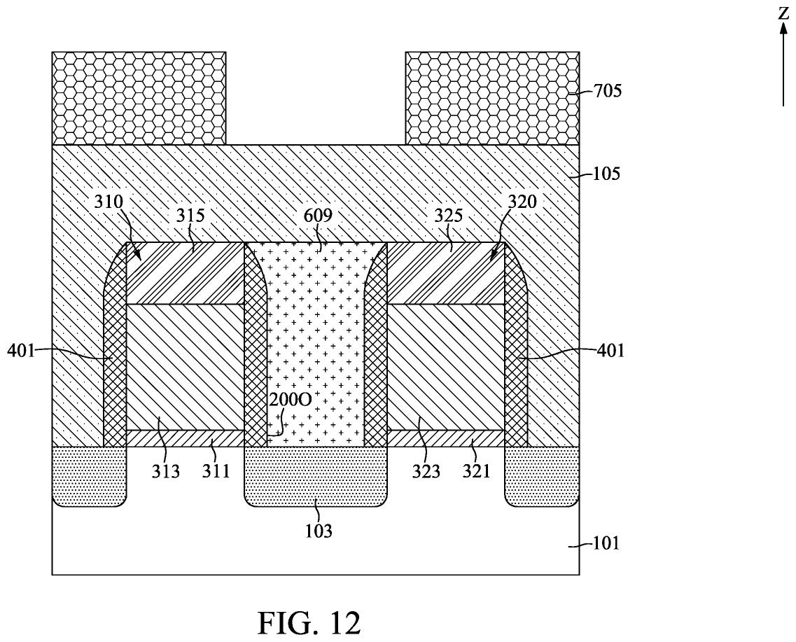

With reference to FIG. 12, a third mask layer 705 may be formed on the dielectric layer 105. The third mask layer 705 may include the pattern of the first opening 1050. In some embodiments, the third mask layer 705 may be a photoresist layer.

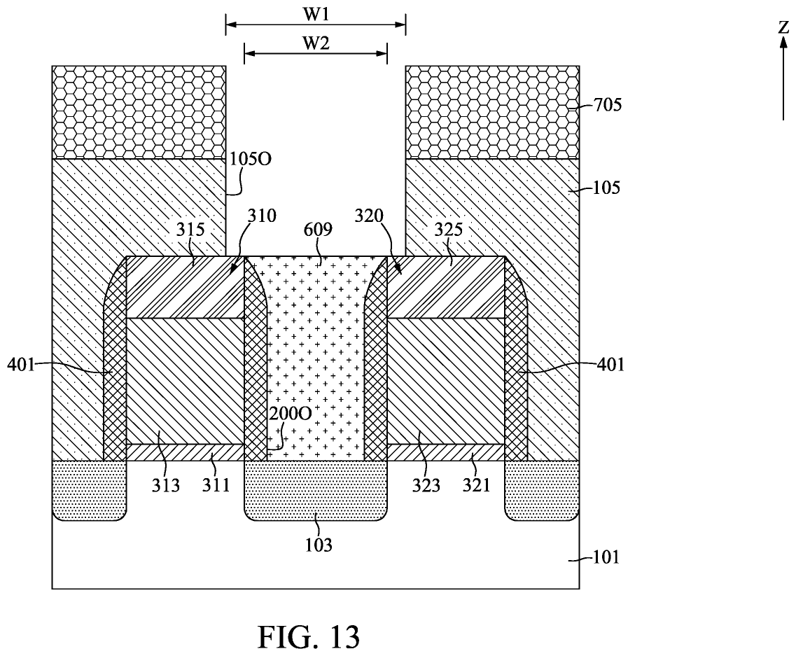

With reference to FIG. 13, a third etching process may be performed to remove a portion of the dielectric layer 105. In some embodiments, the etch rate ratio of the dielectric layer 105 to the third mask layer 705 may be between about 100:1 and about 1.05:1, between about 15:1 and about 2:1, or between about 10:1 and about 2:1 during the third etching process. In some embodiments, the etch rate ratio of the dielectric layer 105 to the energy-removable material 609 may be between about 100:1 and about 1.05:1, between about 15:1 and about 2:1, or between about 10:1 and about 2:1 during the third etching process. After the third etching process, the first opening 1050 may be formed along the first opening 1050 to expose the layer of energy-removable material 609 in the contact opening 2000. After the third etching process, the third mask layer 705 may be removed. In some embodiments, the width W1 of the first opening 1050 may be greater than the width W2 of the contact opening 2000. That is, the layer of energy-removable material 609 in the contact opening 2000 may be completely exposed through the first opening 1050. In some embodiments, the width W2 of the contact opening 2000 may gradually decrease toward the substrate 101 along the direction Z. Due to the etching selectivity of the energy-removable material 609, no additional etching stop layer is required.

With reference to FIGS. 1, 14, and 15, at step S19, the layer of energy-removable material 609 may be removed and the contact structure 200 may be formed in the contact opening 2000 and the first opening 1050.

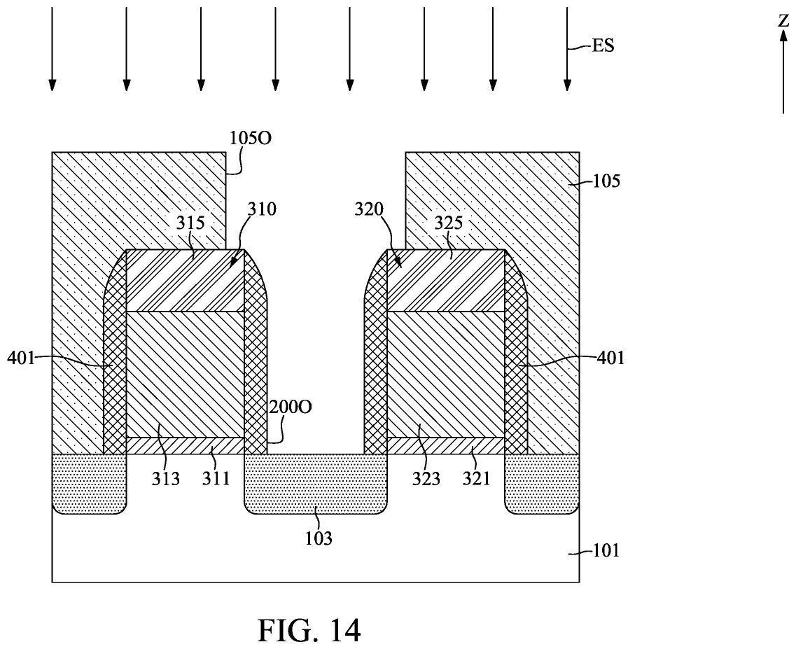

With reference to FIG. 14, a second removal process may be performed to remove the layer of energy-removable material 609 in the contact opening 2000. In some embodiments, the second removal process may be an etching process such as a wet etching process. In some embodiments, the second removal process may be an energy treatment using an energy source ES. The energy source ES may include heat, light, or a combination thereof. When heat is used as the energy source, a temperature of the energy treatment may be between about 800° C. and about 900° C. When light is used as the energy source, an ultraviolet light may be applied. In some embodiments, the removal rate ratio of the energy-removable material 609 to the impurity regions 103 may be between about 100:1 and about 1.05:1, between about 15:1 and about 2:1, or between about 10:1 and about 2:1 during the second removal process. In some embodiments, the removal rate ratio of the energy-removable material 609 to the dielectric layer 105 may be between about 100:1 and about 1.05:1, between about 15:1 and about 2:1, or between about 10:1 and about 2:1 during the second removal process. After the second removal process, the contact opening 2000 and the first opening 1050 may be communicated with each other.

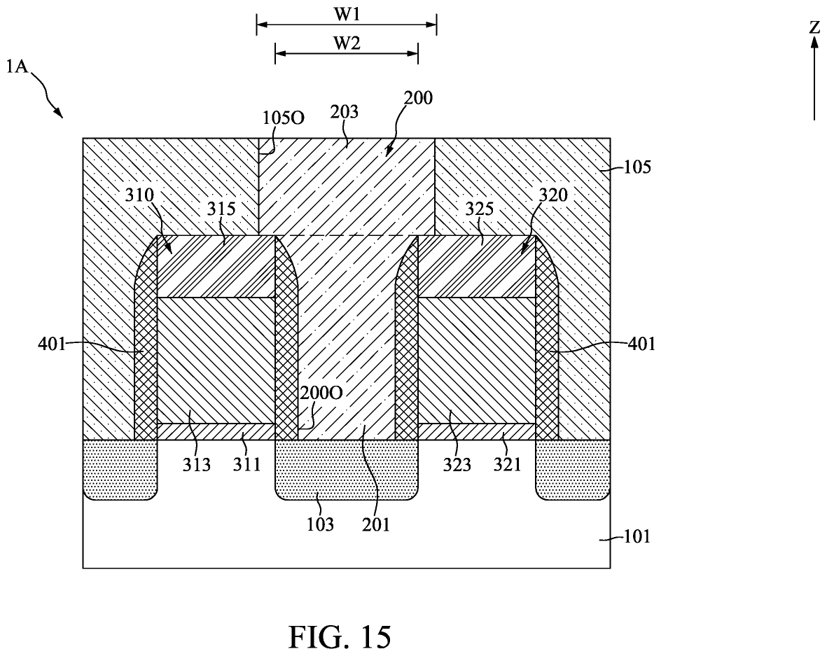

With reference to FIG. 15, a conductive material may be formed to completely fill the contact opening 2000 and the first opening 1050. A planarization process, such as chemical mechanical polishing, may be performed until the top surface of the dielectric layer 105 is exposed to remove excess material, provide a substantially flat surface for subsequent processing steps, and concurrently form the contact structure 200. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference to FIG. 15, the contact structure 200 may include a lower portion 201 and an upper portion 203. The lower portion 201 may be formed in the contact opening 2000. The upper portion 203 may be formed on the lower portion 201 and in the first opening 1050. The shape of the contact structure 200 may be determined by the contact opening 2000 and the first opening 1050. That is, the width W2 of the lower portion 201 may be less than the width W1 of the upper portion 203. The width W2 of the lower portion 201 may gradually decreased toward the substrate 101 along the direction Z.

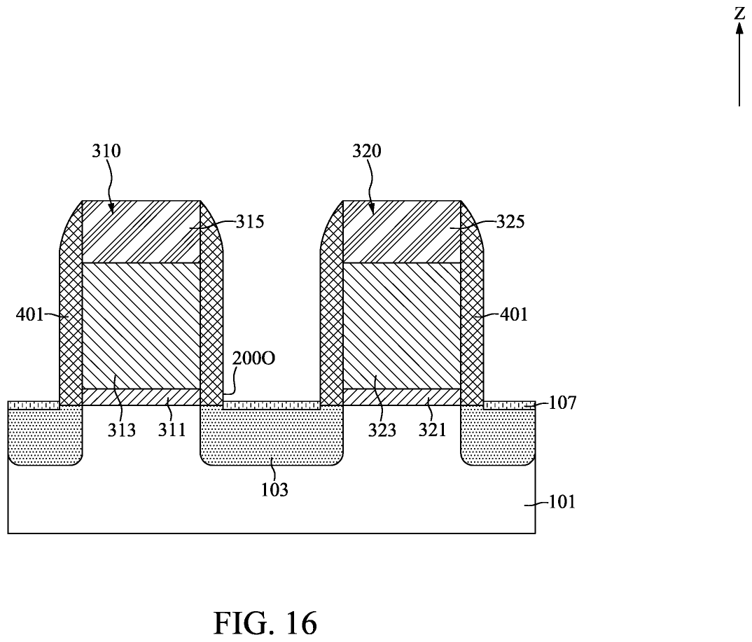

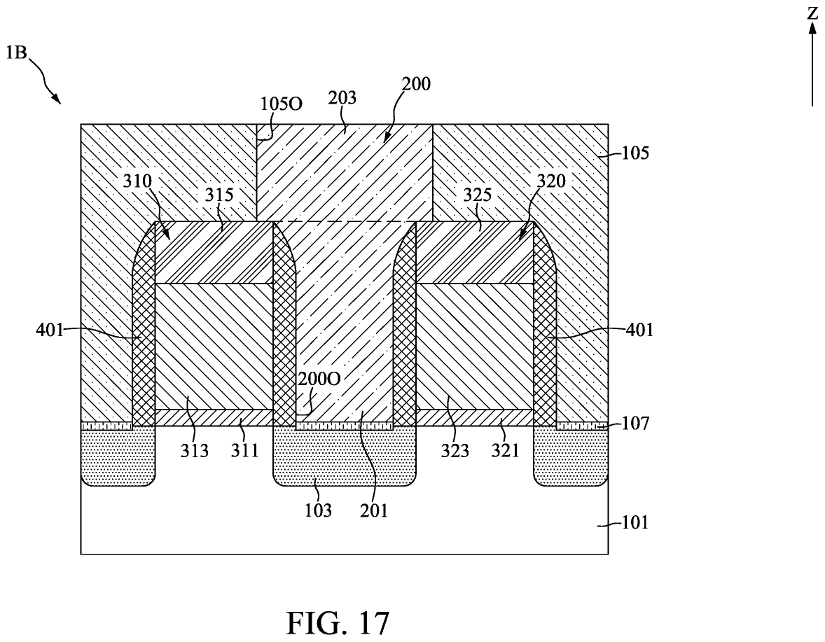

FIGS. 16 and 17 illustrate, in schematic cross-sectional view diagrams, a flow for fabricating a semiconductor device 1B in accordance with another embodiment of the present disclosure.

With reference to FIG. 16, an intermediate semiconductor device may be fabricated with a procedure similar to that illustrated in FIGS. 2 to 7, and descriptions thereof are not repeated herein. A layer of conductive material (not shown) may be conformally formed to cover the plurality of impurity regions 103, the first gate structure 310, and the second gate structure 320. The conductive material may include, for example, titanium, nickel, platinum, tantalum, or cobalt. A thermal treatment may be subsequently performed. During the thermal treatment, metal atoms of the layer of conductive material may react chemically with silicon atoms of the plurality of impurity regions 103 to form a plurality of bottom assistance layers 107. The plurality of bottom assistance layers 107 may include titanium silicide, nickel silicide, nickel platinum silicide, tantalum silicide, or cobalt silicide. The thermal treatment may be a dynamic surface annealing process. After the thermal treatment, a cleaning process may be performed to remove the unreacted conductive material. The cleaning process may use etchant such as hydrogen peroxide and an SC-1 solution. In some embodiments, the thickness of the plurality of bottom assistance layers 107 may be between about 2 nm and about 20 nm.

With reference to FIG. 17, the dielectric layer 105 and the contact structure 200 may be formed with a procedure similar to that illustrated in FIGS. 8 to 15, and descriptions thereof are not repeated herein. The plurality of bottom assistance layers 107 may reduce the resistance between the contact structure 200 and the impurity region 103. As a result, the performance of the semiconductor device 1B may be improved.

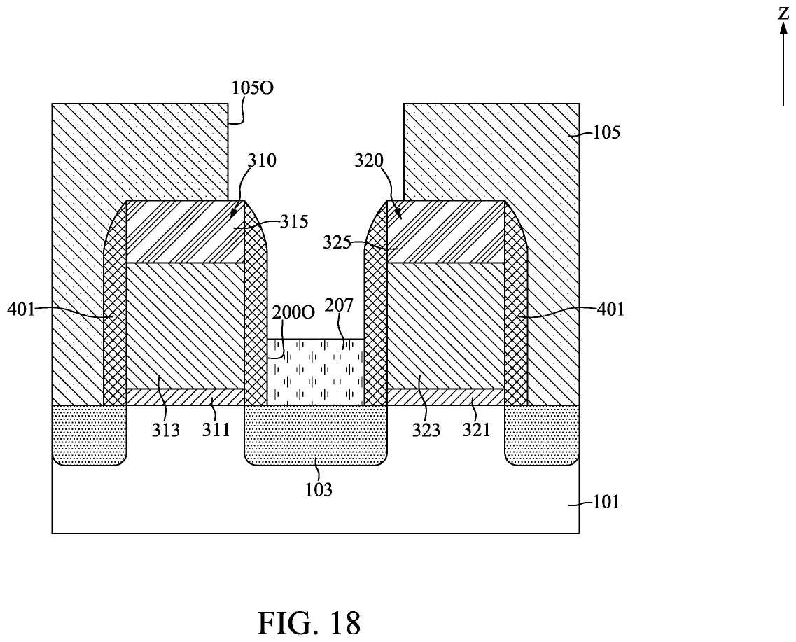

FIGS. 18 to 23 illustrate, in schematic cross-sectional view diagrams, a flow for fabricating a semiconductor device 1C in accordance with another embodiment of the present disclosure.

With reference to FIG. 18, an intermediate semiconductor device may be fabricated with a procedure similar to that illustrated in FIGS. 2 to 14, and descriptions thereof are not repeated herein.

With reference to FIG. 18, a bottom contact conductive layer 207 may be formed in the contact opening 2000 and on the corresponding impurity region 103. Detailedly, the bottom contact conductive layer 207 may be selectively deposited on the impurity region 103 over the plurality of first spacers 401 and the dielectric layer 105. In some embodiments, the bottom contact conductive layer 207 may be formed of, for example, germanium. In some embodiments, the bottom contact conductive layer 207 may include an atomic percentage of germanium greater than or equal to 50%. In this regard, the bottom contact conductive layer 207 may be described as a “germanium-rich layer”. In some embodiments, the atomic percentage of germanium in the bottom contact conductive layer 207 may be greater than or equal to 60%, greater than or equal to 70%, greater than or equal to 80% greater than or equal to 90%, greater than or equal to 95%, greater than or equal to 98%, greater than or equal to 99% or greater than or equal to 99.5%. Stated differently, in some embodiments, the bottom contact conductive layer 207 consists essentially of germanium.

In some embodiments, the bottom contact conductive layer 207 may be formed by a deposition process. In some embodiments, the deposition process may include a reactive gas including a germanium precursor and/or hydrogen gas. In some embodiments, the germanium precursor may consist essentially of germane. In some embodiments, the germanium precursor may include one or more of germane, digermane, isobutylgermane, chlorogermane, or dichlorogermane. In some embodiments, the hydrogen gas may be used as a carrier or diluent for the germanium precursor. In some embodiments, the reactive gas may consist essentially of germane and hydrogen gas. In some embodiments, the molar percentage of germane in the reactive gas may be in a range of about 1% to about 50%, in a range of about 2% to about 30%, or in a range of about 5% to about 20%.

In some embodiments, the temperature of the intermediate semiconductor device to be deposited may be maintained during the deposition process. The temperature may be referred to as the substrate temperature. In some embodiments, the substrate temperature may be in a range between about 300° C. and about 800° C., between about 400° C. and about 800° C., between about 500° C. and about 800° C., between about 250° C. and about 600° C., between about 400° C. and about 600° C., or between about 500° C. and about 600° C. In some embodiments, the substrate temperature may be about 540° C.

In some embodiments, the pressure of the processing chamber for depositing the bottom contact conductive layer 207 may be maintained during the deposition process. In some embodiments, the pressure is maintained in a range between about 1 Torr and about 300 Torr, between about 10 Torr and about 300 Torr, between about 50 Torr and about 300 Torr, between about 100 Torr and 300 Torr, between about 200 Torr and about 300 Torr, or between about 1 Torr and about 20 Torr. In some embodiments, the pressure may be maintained at about 13 Torr.

In some embodiments, the selectivity of the deposition may be greater than or equal to 5, greater than or equal to 10, greater than or equal to 20, greater than or equal to 30, or greater than or equal to 50. In some embodiments, the bottom contact conductive layer 207 may be deposited on the impurity region 103 to a thickness before deposition is observed on the dielectric layer 105.

It should be noted that, in the description of the present disclosure, the term “selectively depositing a layer on a first feature over a second feature”, and the like, means that a first amount of the layer is deposited on the first feature and a second amount of the layer is deposited on the second feature, where the first amount of the layer is greater than the second amount of the layer, or no layer is deposited on the second feature. The selectivity of a deposition process may be expressed as a multiple of growth rate. For example, if one surface is deposited on twenty-five times faster than a different surface, the process would be described as having a selectivity of 25:1 or simply 25. In this regard, higher ratios indicate more selective deposition processes.

The term “over” used in this regard does not imply a physical orientation of one feature on top of another feature, rather a relationship of the thermodynamic or kinetic properties of the chemical reaction with one feature relative to the other feature. For example, selectively depositing a germanium layer onto a silicon surface over a dielectric surface means that the germanium layer deposits on the metal surface and less or no germanium layer deposits on the dielectric surface; or that the formation of a germanium layer on the silicon surface is thermodynamically or kinetically favorable relative to the formation of a germanium layer on the dielectric surface.

In some embodiments, a pre-cleaning process such as wet etch or dry etch may be performed to remove contaminants before the formation of the bottom contact conductive layer 207. In some embodiments, the wet etch process may utilize ammonia or hydrogen fluoride solution. In some embodiments, the dry etch process may be a plasma etch process and may utilize a fluorine or hydrogen containing etchant. The pre-cleaning process would not substantially remove any portion of the impurity region 103.

With reference to FIG. 18, an implantation process may be performed to the bottom contact conductive layer 207. The implantation process may employ n-type dopants or p-type of dopants. The n-type dopants may include but are not limited to antimony, arsenic, and/or phosphorus. The p-type dopants may include, but are not limited to, boron, aluminum, gallium and/or indium. In some embodiments, the dopant concentration of the bottom contact conductive layer 207 and the dopant concentration of the impurity region 103 may be substantially the same. In some embodiments, the dopant concentration of the bottom contact conductive layer 207 and the dopant concentration of the impurity region 103 may be different.

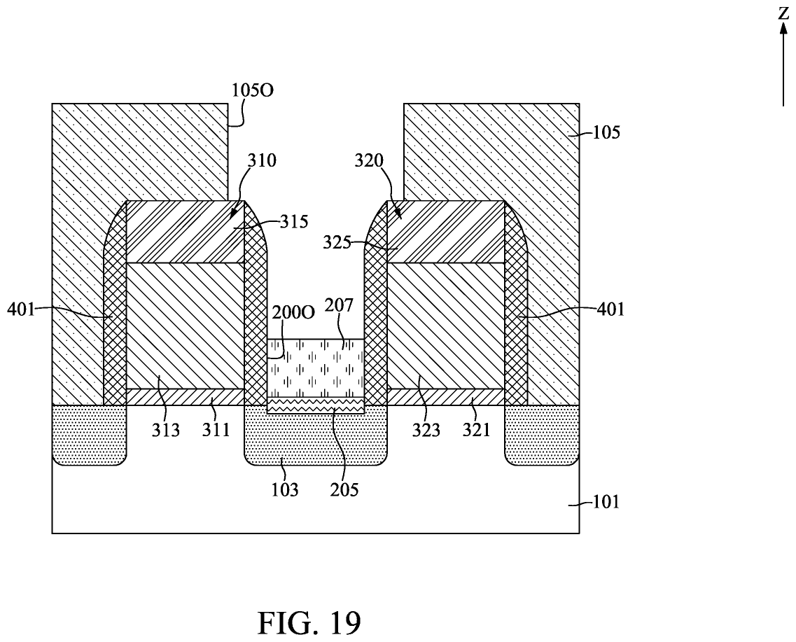

With reference to FIG. 19, an annealing process may be performed to activate the impurity region 103 and the bottom contact conductive layer 207. The annealing process may have a process temperature between about 800° C. and about 1250° C. The annealing process may have a process duration between about 1 millisecond and about 500 milliseconds. The annealing process may be, for example, a rapid thermal annealing, a laser spike annealing, or a flash lamp annealing. After the annealing process, an intervening layer 205 may be formed between the bottom contact conductive layer 207 and the impurity region 103.

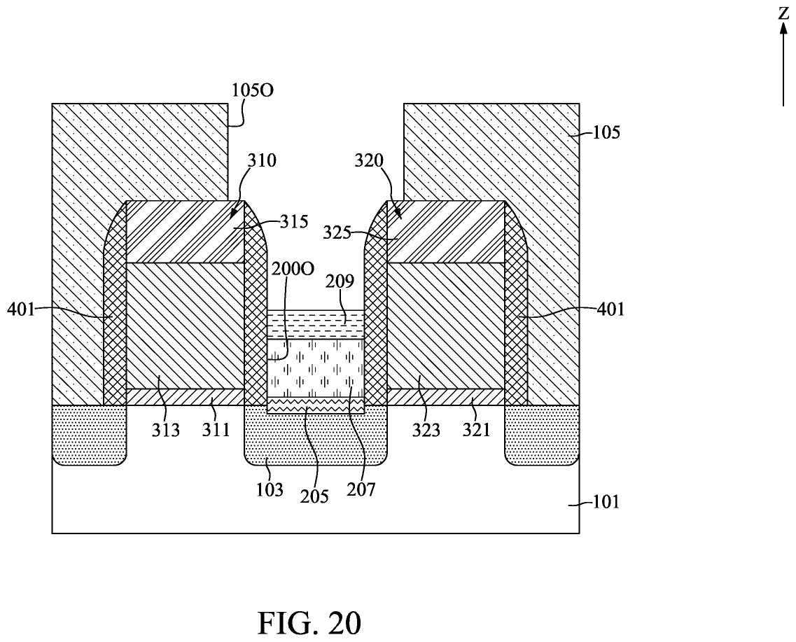

With reference to FIG. 20, a middle contact conductive layer 209 may be formed on the bottom contact conductive layer 207 and in the contact opening 2000. In some embodiments, the middle contact conductive layer 209 may be formed of, for example, tungsten, ruthenium, molybdenum, or alloys thereof. In some embodiments, the middle contact conductive layer 209 may be formed of a metal nitride such as tungsten nitride, titanium nitride, or other applicable conductive metal nitrides. In some embodiments, the middle contact conductive layer 209 may be formed by, for example, low energy physical vapor deposition, chemical vapor deposition, atomic layer deposition, or other applicable deposition processes.

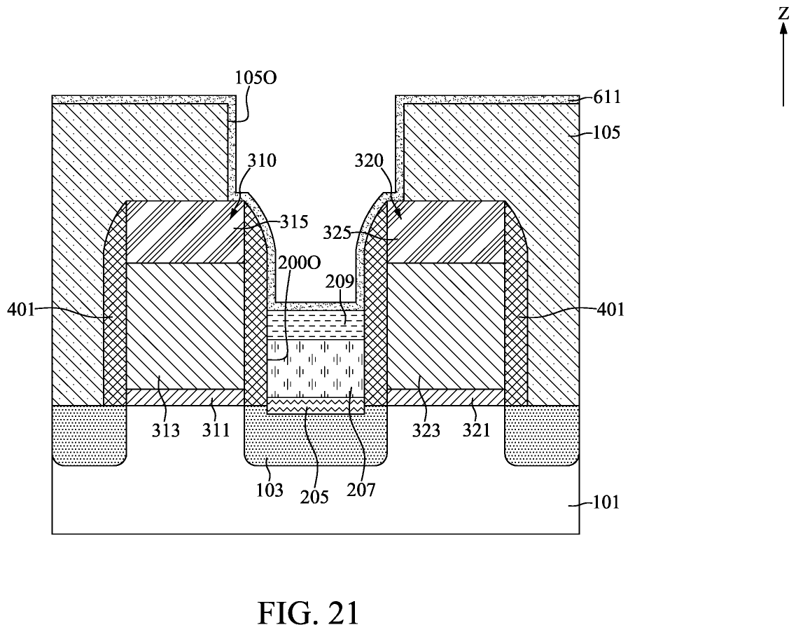

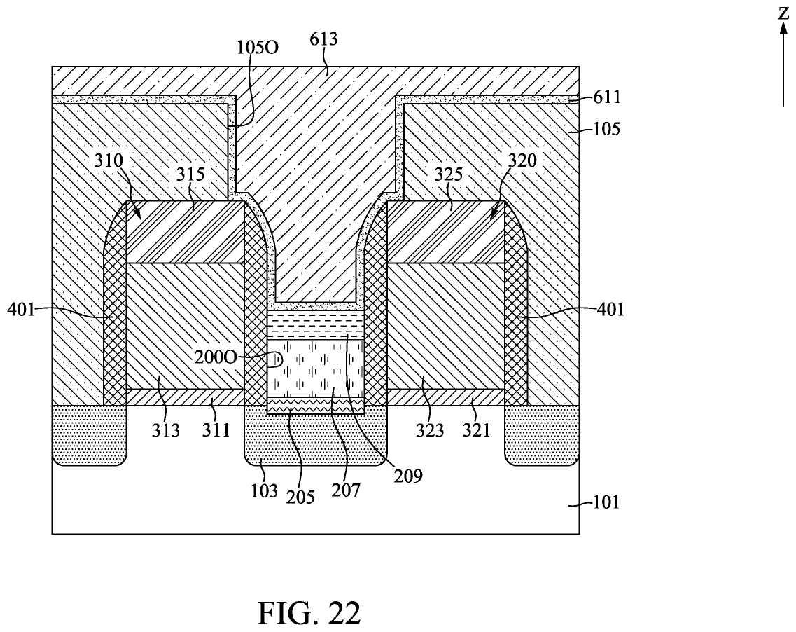

With reference to FIG. 21, a nucleation layer 611 may be conformally formed on the middle contact conductive layer 209, on the plurality of first spacers 401 in the contact opening 2000, and on the dielectric layer 105. A bulk layer 613 (as shown in FIG. 22) which will be illustrated later may be formed on the nucleation layer 611.

With reference to FIG. 21, the nucleation layer 611 and the bulk layer 613 may include tungsten. Tungsten may be particularly useful in integrated circuit devices because of its thermal stability during high temperature processes, where processing temperatures may reach 900° C. or more. Additionally, tungsten is a highly refractive material which offers good oxidation resistance and lower resistivity.

In some embodiments, the nucleation layer 611 may be a thin conformal layer that serves to facilitate the subsequent formation of a bulk material (i.e., the bulk layer 613) thereon. Conforming to the underlying middle contact conductive layer 209 may be critical to support high quality deposition. In some embodiments, the nucleation layer 611 may be formed by a pulsed nucleation layer method.

In the pulsed nucleation layer method, pulses of reactant (e.g., reducing agent or precursor) may be sequentially injected and purged from the reaction chamber, typically by a pulse of a purge gas between reactants. A first reactant may be adsorbed onto the substrate (e.g., the middle contact conductive layer 209), available to react with the next reactant. The process is repeated in a cyclical fashion until the desired thickness is achieved. It should be noted that the pulsed nucleation layer method may be generally distinguished from atomic layer deposition by its higher operating pressure range (greater than 1 Torr) and its higher growth rate per cycle (greater than 1 monolayer film growth per cycle). The chamber pressure during the pulsed nucleation layer method may range from about 1 Torr to about 400 Torr.

In some embodiments, the reactants of forming the nucleation layer 611 may be, for example, a silicon-containing reducing agent and a tungsten-containing precursor. The middle contact conductive layer 209 may be initially exposed to the silicon-containing reducing agent and followed by exposure to the tungsten-containing precursor to form the nucleation layer 611. The exposure to the silicon-containing reducing agent and the tungsten-containing precursor may be defined as a cycle and may be repeated until the desired thickness of the nucleation layer 611 is achieved.

Silane and related compounds have been found to adsorb well to metal nitride surfaces such as titanium nitride and tungsten nitride used as barrier layer materials in some integrated circuit applications. Any suitable silane or silane derivative may be used as the silicon-containing reducing agent, including organic derivatives of silanes. It is generally understood that silanes adsorb on the substrate surface in a self-limiting manner to create nominally a monolayer of silane species. Thus, the amount of adsorbed species is largely independent of the silane dosage.

In some embodiments, the substrate temperature during the exposure to the silicon-containing reducing agent may be between about 200° C. and about 475° C., between about 300° C. and about 400° C., or about 300° C. In some embodiments, the chamber pressure during exposure to the silicon-containing reducing agent may be between about 1 Torr and about 350 Torr or be fixed around 40 Torr. The exposure time (or pulse time) may vary depending in part upon dosages and chamber conditions. In some embodiments, the middle contact conductive layer 209 is exposed until the surface is sufficiently and evenly covered with at least a saturated layer of silane species. In some embodiments, the silicon-containing reducing agent may be provided alone. In some embodiments, the silicon-containing reducing agent may be provided with a carrier gas such as argon or argon-hydrogen mixtures.

In some embodiments, once the middle contact conductive layer 209 is sufficiently covered with silane species, the flow of the silicon-containing reducing agent may be stopped. A purge process may be performed to clear residual gas reactants near the surface of the middle contact conductive layer 209. The purge process may be performed with a carrier gas such as argon, hydrogen, nitrogen, or helium.

In some embodiments, the tungsten-containing precursor may include tungsten hexafluoride, tungsten hexachloride, or tungsten hexacarbonyl. In some embodiments, the tungsten-containing precursor may include organo-metallic compounds that are free of fluorine, such as MDNOW (methylcyclopentadienyl-dicarbonylnitrosyl-tungsten) and EDNOW (ethylcyclopentadienyl-dicarbonylnitrosyl-tungsten). In some embodiments, the tungsten-containing precursor may be provided in a dilution gas, accompanying with gases such as argon, nitrogen, hydrogen, or a combination thereof.

In some embodiments, the substrate temperature during exposure to the tungsten-containing precursor may be between about 200° C. and about 475° C., between about 300° C. and about 400° C., or about 300° C. In some embodiments, the chamber pressure during exposure to the tungsten-containing precursor may be between about 1 Torr and about 350 Torr. Tungsten-containing precursor dosage and substrate exposure time (or pulse time) will vary depending upon many factors. In general, the exposure may be performed until the adsorbed silane species is sufficiently consumed by reaction with the tungsten-containing precursor to produce the nucleation layer 611. Thereafter, the flow of the tungsten-containing precursor may be stopped, and a purge process may be performed with a carrier gas such as argon, hydrogen, nitrogen, or helium.

Alternatively, in some embodiments, the reactants of forming the nucleation layer 611 may be, for example, a boron-containing reducing agent and the tungsten-containing precursor. The middle contact conductive layer 209 may be initially exposed to the boron-containing reducing agent and followed by exposure to the tungsten-containing precursor to form the nucleation layer 611. The exposure to the boron-containing reducing agent and the tungsten-containing precursor may be defined as a cycle and may be repeated until the desired thickness of the nucleation layer 611 is achieved.

In some embodiments, the boron-containing reducing agent may be, for example, borane, diborane, triborane, or boron halides (e.g., BF₃, BCl₃) with hydrogen. The tungsten-containing precursor may be material similar to the tungsten-containing precursor mentioned above, and descriptions thereof are not repeated herein. In some embodiments, the boron-containing reducing agent may be provided in a dilution gas, accompanying with gases such as argon, nitrogen, hydrogen, silane, or a combination thereof. For example, diborane may be provided from a diluted source (e.g., 5% diborane and 95% nitrogen). In some embodiments, the substrate temperature during exposure to the boron-containing reducing agent may be between about 200° C. and about 475° C., between about 300° C. and about 400° C., or about 300° C. In some embodiments, the chamber pressure during exposure to the boron-containing reducing agent may be between about 1 Torr and about 350 Torr. In some embodiments, once the boron-containing reducing agent is deposited to a sufficient thickness, the flow of boron-containing reducing agent may be stopped. A purge process may be performed with a carrier gas such as argon, hydrogen, nitrogen, or helium.

After exposure to the boron-containing reducing agent, the intermediate semiconductor device may be then exposed to the tungsten-containing precursor. The process is similar to that exposure to the tungsten-containing precursor after exposing to the silicon-containing reducing agent, and descriptions thereof are not repeated herein.

In some embodiments, a pre-treatment may be performed to the middle contact conductive layer 209 before forming the nucleation layer 611 using exposure to the boron-containing reducing agent and the tungsten-containing precursor. The pre-treatment may include diborane.

In some embodiments, exemplary data reveals that the diborane-based nucleation layer 611 may produce tungsten with greater grain size in the initial stage of forming the nucleation layer 611. In contrast, the silane-based nucleation layer 611 may produce tungsten with smaller grain size in the initial stage of forming the nucleation layer 611. That is, the deposited bulk layer 613 form on the silane-based nucleation layer 611 may have less or no defects such as seam and void.

Alternatively, the nucleation layer 611 may be formed by being sequentially exposed to the silicon-containing reducing agent, the tungsten-containing precursor, the boron-containing reducing agent, and the tungsten-containing precursor. The four steps of exposure may be defined as a cycle. The entire four-step cycle may be repeated to form the nucleation layer 611 with the desired thickness. In a variation of the process, the first two steps of the cycle (sequential exposure to the silicon-containing reducing agent and the tungsten-containing precursor) may be repeated one or more times prior to contact with the boron-containing reducing agent. In another variation, the last two steps of the cycle (sequential exposure to the boron-containing reducing agent and the tungsten-containing precursor) may be repeated one or more times after the first two steps are completed.

Alternatively, in some embodiments, the reactants of forming the nucleation layer 611 may be, for example, a germanium-containing reducing agent and the tungsten-containing precursor. The middle contact conductive layer 209 may be initially exposed to the germanium-containing reducing agent and followed by exposure to the tungsten-containing precursor to form the nucleation layer 611. In some embodiments, the germanium-containing reducing agent may be a germane such as GeₙHₙHₙ₊₄, GeₙHₙ₊₆, GeₙHₙ₊₈, and GeₙHₘ, where n is an integer from 1 to 10, and n is a different integer than m. Other germanium-containing compounds may also be used, for example, alkyl germanes, alkyl germanium, aminogermanes, carbogermanes, and halogermane. The tungsten-containing precursor may be material similar to the tungsten-containing precursor mentioned above, and descriptions thereof are not repeated herein.

With reference to FIG. 22, the bulk layer 613 may be formed on the nucleation layer 611 and completely fill the contact opening 2000 and the first opening 1050. The bulk layer 613 may be formed by, for example, physical vapor deposition, atomic layer deposition, molecular layer deposition, chemical vapor deposition, in-situ radical assisted deposition, metalorganic chemical vapor deposition, molecular beam epitaxy, sputtering, plating, evaporation, ion beam deposition, electron beam deposition, laser assisted deposition, chemical solution deposition, or any combination thereof.

For example, the deposition of the bulk layer 613 using chemical vapor deposition may include flowing (or introducing) a tungsten-containing precursor and a co-reactant such as a reducing agent to the intermediate semiconductor device including the nucleation layer 611. Example process pressure may be between about 10 Torr and about 500 Torr. Example substrate temperature may be between about 250° C. and about 495° C. The tungsten-containing precursor may be, for example, tungsten hexafluoride, tungsten chloride, or tungsten hexacarbonyl. The reducing agent may be, for example, hydrogen gas, silane, disilane, hydrazine, diborane, or germane.

In some embodiments, the grain size of tungsten of the bulk layer 613 may be greater than 30 nm, than 50 nm, than 70 nm, than 80 nm, than 85 nm, or than 87 nm. In some embodiments, the bulk layer 613 may include alpha phase tungsten.

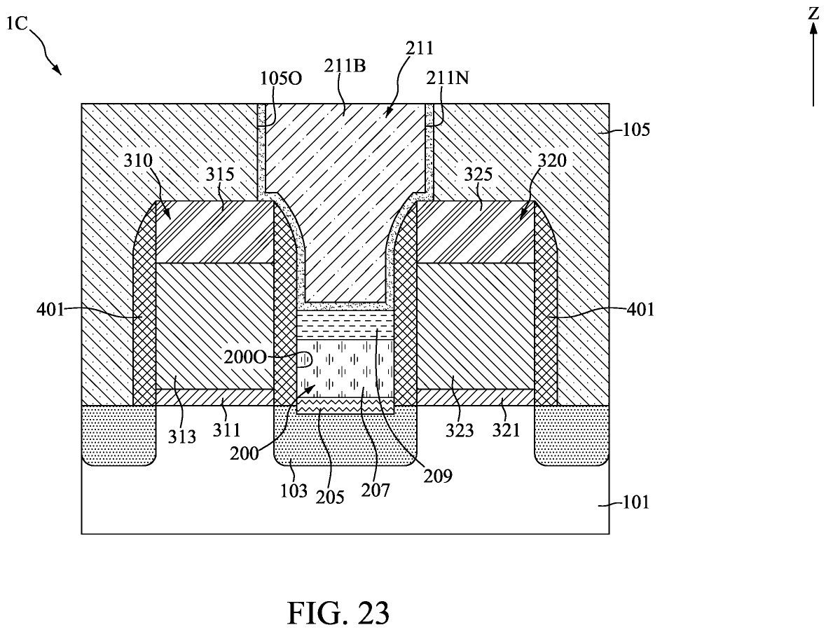

With reference to FIG. 23, a planarization process, such as chemical mechanical polishing, may be performed until the top surface of the dielectric layer 105 is exposed to remove excess material and provide a substantially flat surface for subsequent processing steps. After the planarization process, the remaining nucleation layer 611 may be turned into a nucleation portion 211N. The remaining bulk layer 613 may be turned into a bulk portion 2111B. The nucleation portion 211N and the bulk portion 211B together configure a top contact conductive layer 211 formed on the middle contact conductive layer 209. The intervening layer 205, the bottom contact conductive layer 207, the middle contact conductive layer 209, and the top contact conductive layer 211 together configure the contact structure 200.

By employing the bottom contact conductive layer 207 formed of germanium, the resistance of the contact structure 200 may be reduced. As a result, the performance of the semiconductor device 1C including the contact structure 200 may be improved.

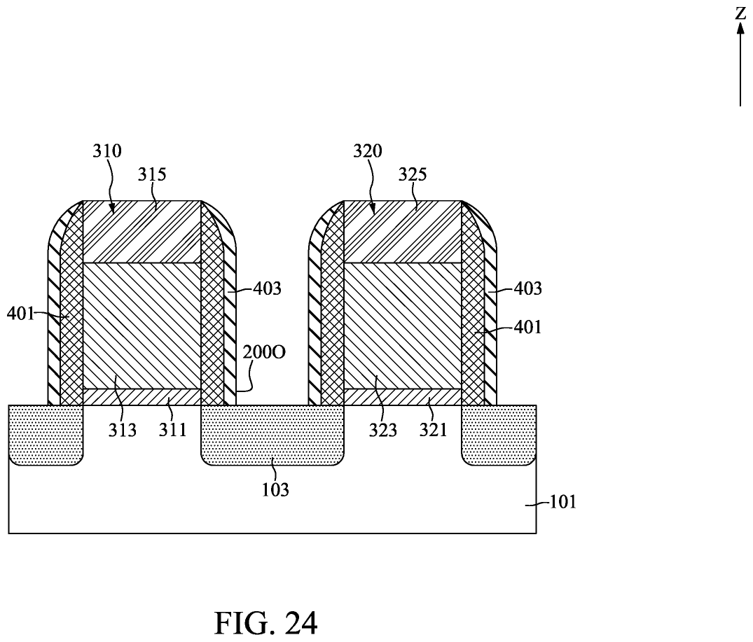

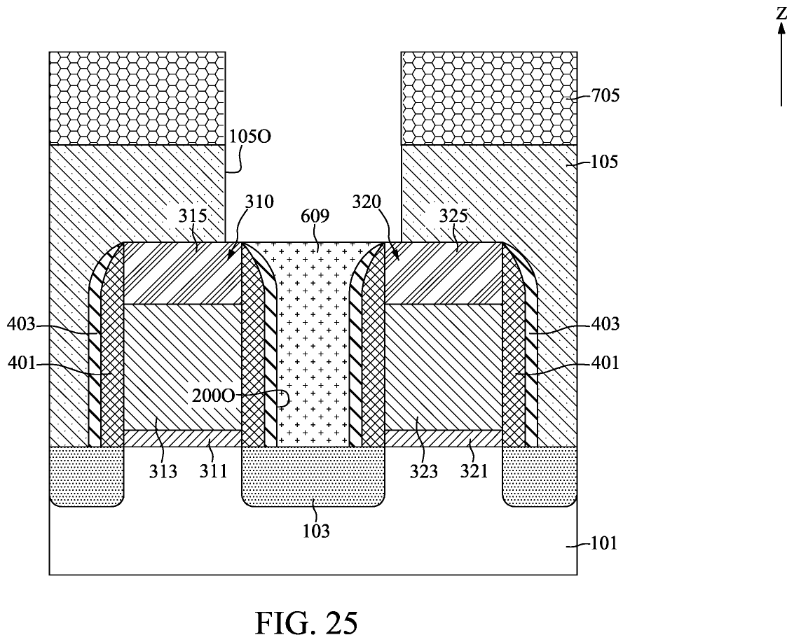

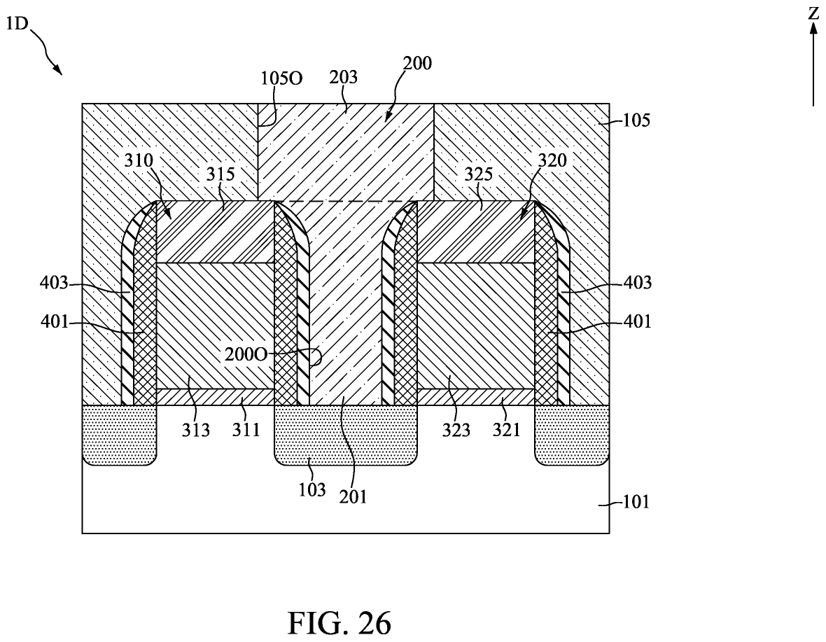

FIGS. 24 to 26 illustrate, in schematic cross-sectional view diagrams, a flow for fabricating a semiconductor device 1D in accordance with another embodiment of the present disclosure.

With reference to FIG. 24, an intermediate semiconductor device may be fabricated with a procedure similar to that illustrated in FIGS. 2 to 7, and descriptions thereof are not repeated herein. A plurality of second spacers 403 may be formed on the plurality of first spacers 401. In some embodiments, the plurality of first spacers 401 may be formed of, for example, silicon oxide, silicon nitride, polysilicon, or the like. In some embodiments, the plurality of second spacers 403 may be formed of, for example, silicon oxide, silicon nitride, or the like. With presence of the plurality of second spacers 403, a thickness of the plurality of first spacers 401 may be minimized, thereby overlap capacitance formed between the plurality of impurity regions 103 and the first gate structure 310 or between the plurality of impurity regions 103 and the second gate structure 320 may be reduced.

One aspect of the present disclosure provides a semiconductor device including a substrate; a first gate structure positioned on the substrate; a second gate structure positioned on the substrate and next to the first gate structure; a layer of energy-removable material positioned on the substrate and between the first gate structure and the second gate structure; a dielectric layer positioned on the substrate and covering the first gate structure and the second gate structure; and a first opening positioned along the dielectric layer to expose the layer of energy-removable material.

Another aspect of the present disclosure provides a semiconductor device including a substrate; a first gate structure positioned on the substrate; a second gate structure positioned on the substrate and next to the first gate structure; a lower portion positioned between the first gate structure and the second gate structure; an upper portion positioned on the lower portion; and a plurality of first spacers positioned between lower portion and the first gate structure and between the lower portion and the second gate structure. The lower portion and the upper portion configure a contact structure. A width of the upper portion is greater than a width of the lower portion.

Another aspect of the present disclosure provides a method for fabricating a semiconductor device including providing a substrate; forming a first gate structure and a second gate structure on the substrate; forming a plurality of first spacers on sidewalls of the first gate structure and the second gate structure; forming a layer of energy-removable material between the first gate structure and the second gate structure; forming a dielectric layer covering the first gate structure, the second gate structure, and the layer of energy-removable material; forming a first opening along the dielectric layer to expose the layer of energy-removable material; removing the layer of energy-removable material to form a contact opening communicated with the first opening; and forming a contact structure in the contact opening and the first opening.

Due to the design of the semiconductor device of the present disclosure, the layer of energy-removable material 609 may be selectively removed. Therefore, no additional etching stop layer is needed for forming the contact structure 200. That is, the short issue originating from an etching stop layer and the contact structure 200 may be avoided. As a result, the yield of the semiconductor device 1A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a first gate structure positioned on the substrate;
a second gate structure positioned on the substrate and next to the first gate structure;
a layer of energy-removable material positioned on the substrate and between the first gate structure and the second gate structure;
a dielectric layer positioned on the substrate and covering the first gate structure and the second gate structure; and
a first opening positioned along the dielectric layer to expose the layer of energy-removable material.

2. The semiconductor device of claim 1, further comprising a plurality of first spacers positioned between the first gate structure and the layer of energy-removable material and between the second gate structure and the layer of energy-removable material.

3. The semiconductor device of claim 2, further comprising an impurity region positioned in the substrate and below the first gate structure and the second gate structure.

4. The semiconductor device of claim 3, wherein the first gate structure comprises:
a first gate insulating layer positioned on the substrate;
a first gate conductive layer positioned on the first gate insulating layer; and
a first gate capping layer positioned on the first gate conductive layer.

5. The semiconductor device of claim 4, wherein a width of the first opening is greater than a width of the layer of energy-removable material.

6. The semiconductor device of claim 5, wherein a top surface of the first gate structure and a top surface of the layer of energy-removable material are substantially coplanar.

7. The semiconductor device of claim 6, wherein the layer of energy-removable material is configured being removed by an energy source.

8. The semiconductor device of claim 7, wherein the plurality of first spacers comprise silicon nitride, silicon oxynitride, or silicon nitride oxide.
wherein the first gate insulating layer comprises a high-k material; wherein the first gate capping layer comprises silicon nitride, silicon oxynitride, or silicon nitride oxide.

9. A semiconductor device, comprising:
a substrate;
a first gate structure positioned on the substrate;
a second gate structure positioned on the substrate and next to the first gate structure;
a lower portion positioned between the first gate structure and the second gate structure;
an upper portion positioned on the lower portion; and
a plurality of first spacers positioned between lower portion and the first gate structure and between the lower portion and the second gate structure;
wherein the lower portion and the upper portion configure a contact structure; wherein a width of the upper portion is greater than a width of the lower portion.

10. The semiconductor device of claim 9, wherein the width of the lower portion is gradually decreased towards the substrate.

11. The semiconductor device of claim 10, further comprising an impurity region positioned in the substrate and below the lower portion, and a dielectric layer positioned on the substrate, covering the first gate structure and the second gate structure, and surrounding the upper portion.

12. The semiconductor device of claim 11, wherein the first gate structure comprises:
a first gate insulating layer positioned on the substrate;
a first gate conductive layer positioned on the first gate insulating layer; and
a first gate capping layer positioned on the first gate conductive layer.
wherein the plurality of first spacers comprise silicon nitride, silicon oxynitride, or silicon nitride oxide; wherein the first gate insulating layer comprises a high-k material.

13. The semiconductor device of claim 12, wherein the first gate capping layer comprises silicon nitride, silicon oxynitride, or silicon nitride oxide; wherein the contact structure comprises tungsten, cobalt, zirconium, tantalum, titanium, aluminum, ruthenium, copper, metal carbides, metal nitrides, transition metal aluminides, or a combination thereof; wherein the impurity region comprises n-type dopants or p-type dopants.

14. A method for fabricating a semiconductor device, comprising:
providing a substrate;
forming a first gate structure and a second gate structure on the substrate;
forming a plurality of first spacers on sidewalls of the first gate structure and the second gate structure;
forming a layer of energy-removable material between the first gate structure and the second gate structure;
forming a dielectric layer covering the first gate structure, the second gate structure, and the layer of energy-removable material;
forming a first opening along the dielectric layer to expose the layer of energy-removable material;
removing the layer of energy-removable material to form a contact opening communicated with the first opening; and
forming a contact structure in the contact opening and the first opening.

15. The method for fabricating the semiconductor device of claim 14, wherein the removing the layer of energy-removable material comprises applying an energy source to the layer of energy-removable material.

16. The method for fabricating the semiconductor device of claim 15, wherein the energy source is light or heat.

17. The method for fabricating the semiconductor device of claim 16, wherein the first gate structure comprises:
a first gate insulating layer formed on the substrate;
a first gate conductive layer formed on the first gate insulating layer; and
a first gate capping layer formed on the first gate conductive layer.
wherein the contact structure comprises a lower portion formed in the contact opening, and an upper portion formed on the lower portion and in the first opening.

18. The method for fabricating the semiconductor device of claim 17, wherein the plurality of first spacers comprise silicon nitride, silicon oxynitride, or silicon nitride oxide.
wherein the first gate insulating layer comprises a high-k material.

19. The method for fabricating the semiconductor device of claim 18, wherein the first gate capping layer comprises silicon nitride, silicon oxynitride, or silicon nitride oxide.
wherein the contact structure comprises tungsten, cobalt, zirconium, tantalum, titanium, aluminum, ruthenium, copper, metal carbides, metal nitrides, transition metal aluminides, or a combination thereof.

20. The method for fabricating the semiconductor device of claim 19, further comprising forming an impurity region in the substrate, wherein the impurity region is between the first gate structure and the second gate structure.
